(19) United States
(12) Patent Application Publication
(10) Pub. No.: US 2021/0179431 A1
(43) Pub. Date: Jun. 17, 2021

(54) CARBON NANOTUBE ATTACHED MEMBER, METHOD FOR MANUFACTURING THE SAME, AND DEVICE FOR MANUFACTURING THE SAME

(71) Applicants: DENSO CORPORATION, Kariya-city, Aichi-pref. (JP); WASEDA UNIVERSITY, Shinjuku-ku, Tokyo (JP)

(72) Inventors: Aun OTA, Kariya-city (JP); Hisayoshi OSHIMA, Kariya-city (JP); Suguru NODA, Shinjuku-ku, Tokyo (JP); Yu YOSHIHARA, Shinjuku-ku, Tokyo (JP)

(21) Appl. No.: 16/078,809

(22) PCT Filed: Oct. 21, 2016
(86) PCT No.: PCT/JP2016/081204

§ 371 Date: Aug. 22, 2018

(30) Foreign Application Priority Data
Feb. 26, 2016 (JP) 2016-035991

(51) Int. Cl. C01B 32/162; B01J 21/04; B01J 23/745; B01J 37/02; B01J 37/08; B01J 15/00

(52) U.S. Cl. CPC C01B 32/162; B01J 21/04; B01J 23/745; B01J 37/0225; C01P 2004/03; B01J 15/005; C01B 2202/08; C01B 2202/34; C01B 2202/24; B01J 37/08

(57) ABSTRACT

A carbon nanotube attached member has a substrate, which is mainly made of aluminum, and a aligned CNT film which is aligned along an alignment direction ORD. A carbon nanotube/CNT, which forms the aligned CNT film, has a length of 200 micrometers or longer. The CNT is synthesized starting from a mixed gas of acetylene, hydrogen, and argon. Furthermore, carbon dioxide is added to maintain catalyst activity. A ratio of acetylene:carbon dioxide is adjusted from 1:10 to 1:300. The aligned CNT film is partially formed. The formation range of the aligned CNT film is set by inhibiting synthesis and/or aligned growth of the CNT by a rough surface or a carbon-containing substance.

### CROSS REFERENCE TO RELATED APPLICATIONS

This application is based on Japanese Patent Application No. 2016-35991 filed on Feb. 26, 2016, the disclosure of which is incorporated herein by reference.

### TECHNICAL FIELD

The disclosure in this specification is relates to a carbon nanotube attached member, a method for manufacturing the same, and a device for manufacturing the same.

### BACKGROUND

A synthesizing method for a carbon nanotube (CNT), i.e., a manufacturing method is known. The method includes the steps of forming a metal as a catalyst on a substrate, and after placing it in a heated furnace, and supplying in the furnace gas containing carbon, such as acetylene, ethanol, etc. which is used as a raw material. For resolving the gas and for maintaining the catalytic activity, the temperature in the furnace is usually maintained at about 700 degrees Celsius (° C.)-800° C. However, according to this technique, it is difficult to perform applications to various materials of the substrate, patterning which form an aligned CNT film in which a plurality of CNTs are aligned in a single direction and are arranged in a bundle fashion in a required area.

Patent Literature 1 discloses a technique which forms an aligned CNT film on a predetermined area on a substrate. Patent Literature 1 is enabling formations of the patterned aligned CNT film by forming, i.e., by patterning, a catalyst necessary for a CNT synthesis on a required area.

Patent Literature 2 proposes a method of synthesizing a CNT at comparatively low temperature. Patent Literature 2 uses the point-discharge type plasma CVD in addition to the usual thermal decomposition, in order to synthesize the CNT in 600 degrees Celsius (° C.) or more and 660° C. or less. Thereby, H2 gas and CH4 are activated and the aligned CNT film is synthesized.

Patent Literature 3 proposes a method of synthesizing the CNT on aluminum or magnesium.

The content of Patent Literatures listed as prior art are used and incorporated by reference as description for technical components disclosed in this description.

### CITATION LIST

### Patent Literature

Patent Literature 1: JP2002-530805

Patent Literature 2: JP2009-78956

Patent Literature 3: JP2011-132068

### SUMMARY

A measure in Patent Literature 1 requires means for forming the patterned catalyst on a required area. Since it requires, for example, a stencil mask or a photolithography, etc., a manufacturing process becomes complicated. In addition, the measure in Patent Literature 1 is restricted to an application to a flat substrate. As a result, for example, it is impossible to form the patterned aligned CNT film on a surface of a three-dimensional structure.

In a measure in Patent Literature 2, the activity of a catalyst cannot maintain for a long period of time. Accordingly, it is impossible to obtain a CNT with long length.

In a measure in Patent Literature 3, since the CNT is arranged randomly, no aligned film is formed.

In the above-mentioned viewpoint, or in the other viewpoint not mentioned above, further improvement is still required for a carbon nanotube attached member, a method for manufacturing the same, and a device for manufacturing the same.

It is a disclosed object to provide a carbon nanotube attached member which has long and aligned CNTs, a method for manufacturing the same, and a device for manufacturing the same.

It is a disclosed another object to provide a carbon nanotube attached member which is partially formed with a aligned CNT film, a method for manufacturing the same, and a device for manufacturing the same.

It is a disclosed another object to provide a carbon nanotube attached member which is formed with a aligned CNT film which is formed by long CNTs, and is formed on a surface of a substrate mainly made of aluminum, a method for manufacturing the same, and a device for manufacturing the same.

It is a disclosed another object to provide a carbon nanotube attached member which is formed with a aligned CNT film and permits brazing of a substrate mainly made of aluminum, and synthesizing CNTs by using a simple device, a method for manufacturing the same, and a device for manufacturing the same.

A carbon nanotube attached member disclosed comprises: a substrate (11) which is mainly made of aluminum; and an aligned CNT film (31, 931) which is arranged on a surface of the substrate, and includes a plurality of carbon nanotubes having a length of 200 micrometers or longer and being aligned along a predetermined alignment direction.

According to the carbon nanotube attached member disclosed, it is possible to provide an aligned CNT film in which a plurality of carbon nanotubes having a length of 200 micrometers or longer are aligned on a substrate mainly made of aluminum.

A manufacturing method for a carbon nanotube attached member disclosed comprises: arranging (183, 283) a catalyst (21, 221) for synthesizing a carbon nanotube on a surface of a substrate mainly made of aluminum; and synthesizing a carbon nanotube on the surface of the substrate in an atmosphere which is supplied with carbon dioxide for maintaining an activity of the catalyst, and volume ratio of carbon dioxide and acetylene being 1:10 or more as a raw material of the carbon nanotube.

According to the manufacturing method disclosed, the activity of the catalyst is maintained in low temperature by carbon dioxide. Therefore, it is possible to synthesize the carbon nanotube in low temperature. As a result, it is possible to form the aligned CNT film on the surface of the substrate mainly made of aluminum.

A device for manufacturing a carbon nanotube attached member disclosed comprises: a heat chamber (61) which accommodates a substrate (11) which is mainly made of aluminum and has a brazing material (313) at least partially, and brazes the substrate by melting a brazing material by heating the substrate; and a material providing machine (66) which supplies raw material of the carbon nanotube to the heat chamber so that the brazing and synthesizing a aligned CNT film (31, 931) in which a plurality of carbon nanotubes are aligned along a predetermined alignment direction is performed in the heat chamber.

According to the manufacturing device indicated, brazing and synthesizing a carbon nanotube can be performed in a common heat chamber.

In order to achieve each object, a plurality of embodiments disclosed in this specification use technical measures different each other. Symbols in parenthesis shown in the above section and in the claim merely show correspondences to elements described in embodiments later mentioned as one example, and are not intended to limit the technical scope of this disclosure. Objects, features, and advantages disclosed in this specification may become clearer by referring to the following descriptions and attached drawings.

### BRIEF DESCRIPTION OF THE DRAWINGS

FIG. 1 is a cross sectional view showing a substrate of a carbon nanotube attached member (a CNT attached member) according to a first embodiment.

FIG. 2 is a cross sectional view in a middle stage of the first embodiment.

FIG. 3 is a cross sectional view showing the CNT attached member according to the first embodiment.

FIG. 4 is a flow chart showing a manufacturing process of the first embodiment.

FIG. 5 is a diagram showing the CNT height of the first embodiment.

FIG. 6 is a cross sectional view in the middle stage of the second embodiment.

FIG. 7 is a cross sectional view showing a CNT attached member according to a second embodiment.

FIG. 8 is a flow chart showing a manufacturing process of the second embodiment.

FIG. 9 is a cross sectional view in the middle stage of a third embodiment.

FIG. 10 is a cross sectional view in the middle stage of the third embodiment.

FIG. 11 is a cross sectional view showing a CNT attached member according to the third embodiment.

FIG. 12 is a diagram showing the CNT height of the third embodiment.

FIG. 13 is a diagram showing the CNT height of the third embodiment.

FIG. 14 is a chart showing components of the brazing material layer of the third embodiment.

FIG. 15 is a cross sectional view in the middle stage of a fourth embodiment.

FIG. 16 is a flow chart showing a manufacturing process of the fourth embodiment.

FIG. 17 is a SEM image showing the CNT attached member of the fourth embodiment.

FIG. 18 is a drawing for explaining the SEM image illustrated in FIG. 17.

FIG. 19 is a cross sectional view showing a variant of the fourth embodiment.

FIG. 20 is a cross sectional view in the middle stage of a fifth embodiment.

FIG. 21 is a cross sectional view in the middle stage of the fifth embodiment.

FIG. 22 is a cross sectional view showing a CNT attached member according to the fifth embodiment.

FIG. 23 is a flow chart showing a manufacturing process of the fifth embodiment.

FIG. 24 is a perspective view showing a CNT attached member according to a sixth embodiment.

FIG. 25 is a perspective view showing a CNT attached member according to a seventh embodiment.

FIG. 26 is a perspective view showing a CNT attached member according to an eighth embodiment.

FIG. 27 is a perspective view showing a CNT attached member according to a ninth embodiment.

FIG. 28 is a cross sectional view showing a CNT attached member according to the ninth embodiment.

FIG. 29 is a cross sectional view showing a CNT attached member according to the ninth embodiment.

FIG. 30 is a block diagram showing a manufacturing device of the ninth embodiment.

FIG. 31 is a flow chart showing a manufacturing process of the fifth embodiment.

FIG. 32 is a cross-sectional view showing a variant of the ninth embodiment.

### DETAILED DESCRIPTION

A plurality of embodiments are described referring to the drawings. In the embodiments, portions, which may be corresponded and/or associated in functionally and/or structurally, may be indicated by the same reference symbols or reference symbols which merely differs at hundred or above digits. Description of other embodiment can be referred to for corresponding portions and/or associated portions.

### First Embodiment

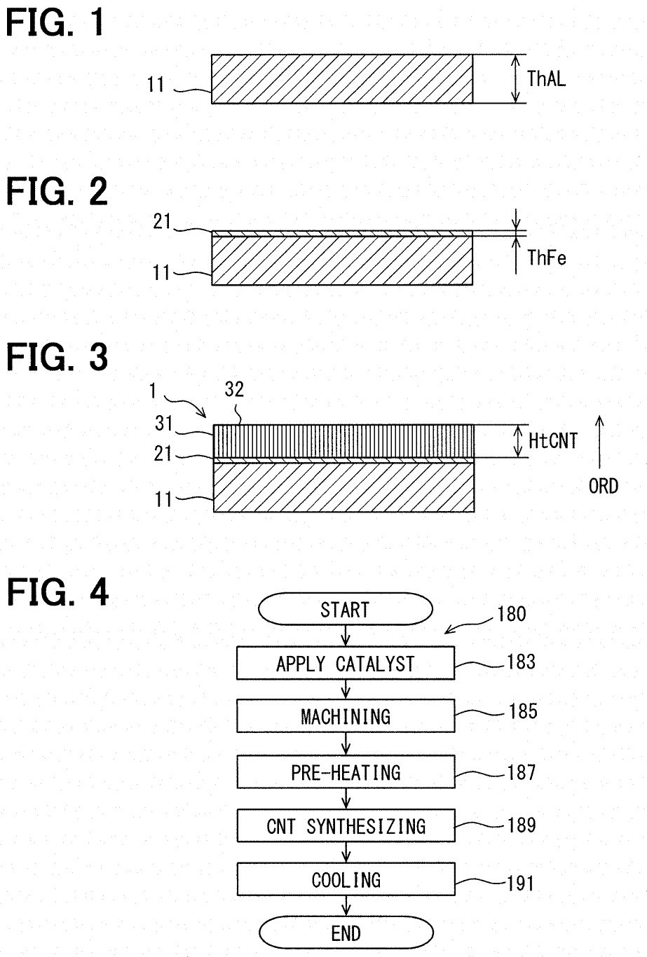

In this embodiment, a carbon nanotube attached member (CNT attached member) and a manufacturing method for the same are disclosed. An aligned carbon nanotube film (aligned CNT film) is a film in which many carbon nanotubes (CNT) are aligned. The aligned CNT film is arranged on a surface of a metal substrate. In an example, the CNTs are aligned to extend vertically to the flat surface provided by the surface of the substrate. A CNT attached member is also called a member covered with the CNTs, a CNT composite material, or a CNT structure. FIG. 1, FIG. 2, and FIG. 3 show shapes of the material in each stage of the manufacturing process of the CNT attached member.

FIG. 1 shows a cross section of the substrate 11 on which CNT is formed. The substrate 11 is a metal plate made of aluminum. The substrate 11 is made of aluminum with 99% or more of purity or an aluminum alloy. The aluminum alloy may include at least one or more additional metal chosen from Si, Zn, Ti, Mn, Cu, Fe, Mg, and Cr. The substrate 11 has a thickness ThAL. The substrate 11 can have arbitrary thickness. For example, the substrate 11 may have a thickness which can be called a foil. The substrate 11 provides a surface spreading in two-dimensional manner. The substrate 11 is a configured object which can maintain a shape of surfaces by itself. In addition, the substrate 11 may have a thickness as a structural member which can form a heat transfer product, such as a radiator or a heat exchanger.

FIG. 2 shows the catalyst layer 21 formed in the front surface of a substrate 11. The catalyst layer 21 is formed by a metal material for synthesizing the CNT. The catalyst layer 21 is formed, for example with iron, nickel, cobalt, etc. In this embodiment, the catalyst layer 21 is formed to cover whole surface of the substrate 11. The catalyst layer 21 has thickness ThFe.

FIG. 3 shows the cross section of the CNT attached member 1. The catalyst layer 21 is arranged on the surface of the substrate 11. An aligned CNT film 31 is formed on the catalyst layer 21. The aligned CNT film 31 has many CNTs. These many CNTs are aligned towards an alignment direction ORD. In the illustrated example, the many CNTs are aligned so that a longitudinal direction of CNT extends along a perpendicular direction to the surface of the substrate 11. The alignment direction ORD may incline to the surface of the substrate 11. The CNT extends along the alignment direction ORD while slightly meandering. The aligned CNT film 31 has height HtCNT along the alignment direction ORD.

The aligned CNT film 31 spreads over whole of the surface of the substrate 11. The aligned CNT film 31 is projected to form a projection 32 on the substrate 11. The height HtCNT almost corresponds to the length of one CNT. One CNT extends along the alignment direction ORD while winding. Therefore, the length of one CNT is longer than the height HtCNT. The Height HtCNT is the height which can use effectively a high thermal conductivity of the CNT as a heat transfer product, such as a radiator or a heat exchanger. For example, when the CNT come in contact with air, the aligned CNT film 31 provides large surface area to air. In addition, the CNT provides high thermal conductivity along the longitudinal direction of the CNT from the substrate 11. As a result, the aligned CNT film 31 promotes heat exchange between air and the substrate 11.

In FIG. 4, the manufacturing method 180 of the CNT attached member 1 has a plurality of phases for forming the aligned CNT film 31 on the surface of the substrate 11. The manufacturing method 180 is performed after arranging the substrate 11 in a heating chamber for synthesizing the CNT. The illustrated order is an example, and may be changed according to an additional request.

The manufacturing method 180 has a plurality of process, i.e., steps. The manufacturing method 180 has a catalyst applying process 183. The catalyst applying process 183 forms the catalyst layer 21 on the surface of the substrate 11. The catalyst layer 21 can be formed by either one of various measures, such as a liquid coating, a vapor depositing, sputtering, and a gaseous phase addition. The manufacturing method 180 can have a shape machining process 185. The shape machining process 185 is prepared as an option. The substrate 11 is processed into a predetermined shape, for example, a three-dimensional shape, in the shape machining process 185. Here, mechanical processing of cutting, bending, etc. is performed. The manufacturing method 180 has a preheating process 187. The preheating process 187 preheats the substrate 11 and the catalyst layer 21 to a temperature suitable for synthesizing the CNT.

The manufacturing method 180 has a CNT synthesizing process 189. In the CNT synthesizing process 189, the raw material of the CNT is supplied into the heating chamber. The raw material is heated and resolved in the heating chamber. The CNT is synthesized on the catalyst which forms the catalyst layer 21. The CNT grows along the alignment direction ORD. As a result, the aligned CNT film 31 is formed. The manufacturing method 180 has a cooling process 191. The cooling process 191 cools the CNT attached member 1, for example, to a room temperature.

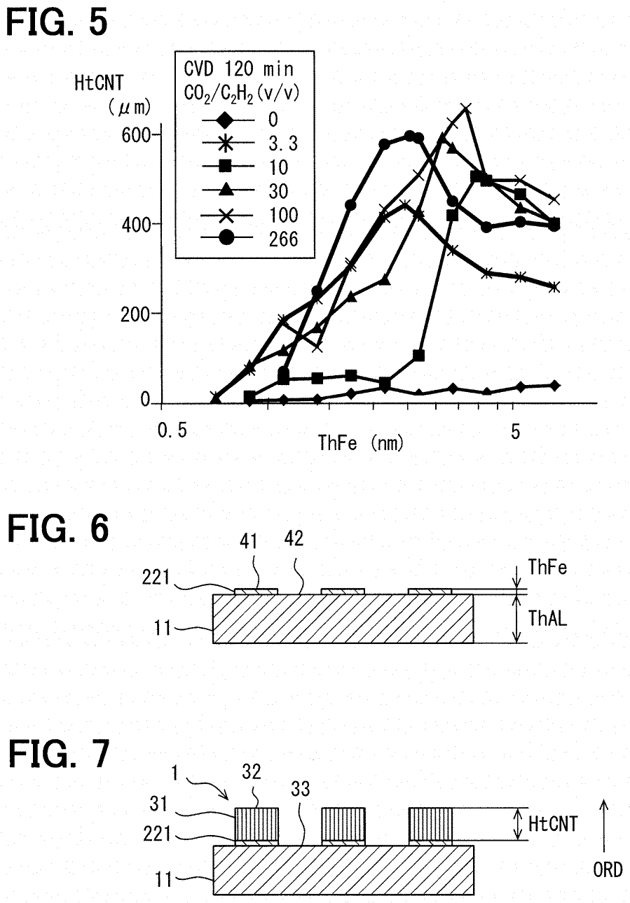

FIG. 5 shows the diagrammatic chart which shows a relationship among a plurality of parameters in the manufacturing method and a CNT height HtCNT (μm: micrometer). The parameters are a volume ratio CO2/C2H2 of the CNT raw material (v/v), and a thickness ThFe (nm: nanometer) of the catalyst layer 21. This diagrammatic chart shows the CNT height HtCNT on the following conditions.

In the catalyst applying process 183, the catalyst layer 21 is formed by a spattering method on the substrate 11. The catalyst layer 21 is formed by depositing iron in a range of 0 nm to 8 nm. The substrate 11 is made of aluminum with 99% of purity, and is a 0.2 mm thick foil. The shape machining process 185 is not performed in this example.

In the preheating process 187, the substrate 11 and the catalyst layer 21 is heated up to 600 degrees Celsius (° C.) in a mixed gas of argon and hydrogen, and they are held for 5 minutes in the 600° C. atmosphere.

In the CNT synthesizing process 189, a source gas of the CNT is supplied on the catalyst layer 21. The source gas is a mixture of acetylene (C₂H₂) and carbon dioxide (CO₂) with volume ratio 1:0-1:266. As a result, the atmosphere in the CNT synthesizing process, i.e., source gas, is a mixed gas of acetylene, hydrogen, carbon dioxide, and argon. The carbon dioxide is added as gas for maintaining the activity of the catalyst. The CNT synthesizing process 189 synthesizes the CNT on the surface of the substrate 11 in the atmosphere in which volume ratio of acetylene and carbon dioxide is 1:10 or more and 1:300 or less as a raw material of the CNT. The CNT synthesis can also be called a thermal-energy CVD operation. The CNT synthesizing process 189 is performed for 120 minutes. In addition, the manufacturing device has a controller which controls an amount of acetylene, and an amount of carbon dioxide.

As shown in the drawing, growth of the aligned CNT film 31 is promoted in a range of volume ratio 1:3.3-1:266, or in a range of volume ratio 1:10-1:266. In all volume ratios, the height HtCNT of the aligned CNT film 31 records peak values, when the thickness ThFe is in a range about 2 nm-3 nm. In all volume ratios, the aligned CNT film 31 of the height exceeding 400 micrometers can be obtained.

As shown in the drawing, in volume ratio 1:3.3, it is possible to obtain the aligned CNT film 31 with height of 400 micrometers or more. In volume ratio 1:10, it is possible to obtain the aligned CNT film 31 with height of 400 micrometers or more on the catalyst layer 21 of the thickness 3 nm and more. The highest aligned CNT film 31 is obtained in volume ratio 1:100. Further, also in volume ratio 1:266, the aligned CNT film 31 with height more than 500 micrometers or 600 micrometers is obtained.

According to inventors' knowledge, it was thought that synthesis of the CNT is unstable in volume ratio lesser than 1:10. On the other hand, high aligned CNT film 31 can be synthesized even in volume ratio 1:300. Therefore, it is thought that the aligned CNT film 31 with height exceeding 200 micrometers, 300 micrometers, or 400 micrometers, still more desirably 500 micrometers can be obtained, in a range of volume ratio 1:10 or more and 1:300 or less.

Volume ratio of acetylene and carbon dioxide in the CNT raw material may be set to 1:10 or more and 1:300 or less. Volume ratio of the CNT raw material may be set to 1:30 or more and 1:100 or less. The thickness ThFe of the catalyst layer 21 can be set near 3 nm, when the catalyst is iron. For example, the thickness ThFe of the catalyst layer 21 can be set as not less than 2 nm. The thickness ThFe of the catalyst layer 21 may be set as not less than 3 nm. These settings make it possible to synthesize high aligned CNT film 31 stably. The thickness ThFe of the catalyst layer 21 can be set as 6 nm or less. The thickness ThFe of the catalyst layer 21 may be set as 5 nm or less. These lower limit and upper limit can be chosen so that the aligned CNT film 31 higher than a predetermined height may be obtained. An inclination of the height HtCNT slopes gently in an area where the thickness ThFe of the catalyst layer 21 exceeds 3 nm. Then, the thickness ThFe of the catalyst layer 21 may be set to a comparatively thick area, for example, where 3 nm or more and 5 nm or less.

According to this embodiment, a high aligned CNT film 31 is formed on the substrate 11 made of aluminum. Specifically, the aligned CNT film 31 which has height not less than 200 micrometers or exceeding 200 micrometers can be obtained. Furthermore, the aligned CNT film 31 which has height not less than 300 micrometers can be obtained. Further in a desirable mode, the aligned CNT film 31 with height of not less than 400 micrometers can be obtained.

### Second Embodiment

This embodiment is one of modifications based on a basic form provided by the preceding embodiment. In the preceding embodiment, the aligned CNT film 31 is formed on a whole surface of the substrate 11. Alternatively, in this embodiment, the aligned CNT film 31 is formed on a part of the surface of the substrate 11.

In FIG. 6, a partial catalyst layer 221 is formed on the surface of the substrate 11 so as to cover a part of the surface of the substrate 11. The catalyst layer 221 is formed on an alignment area 41 to which the formation of the aligned CNT film 31 is expected. The catalyst layer 221 is not formed on a non-formation area 42 to which the formation of the aligned CNT film 31 is not expected. As a result, the surface of the substrate 11 has the alignment area 41 and the non-formation area 42. In the non-formation area 42, the aligned CNT film 31 is not synthesized or is not grown long.

In FIG. 7, the CNT attached member 1 has projections 32 and depressions 33. The projection 32 is a bundle of long CNTs formed to project from the substrate 11. The projection 32 can also be called an island shaped aligned CNT film 31. On the surface of the substrate 11, a plurality of projections 32 spaced apart each other in arbitrary cross sections are formed. The depression 33 is located between two projections 32. At the depression 33, the CNT is not synthesized, or the CNT is extended more roughly than the aligned CNT film 31.

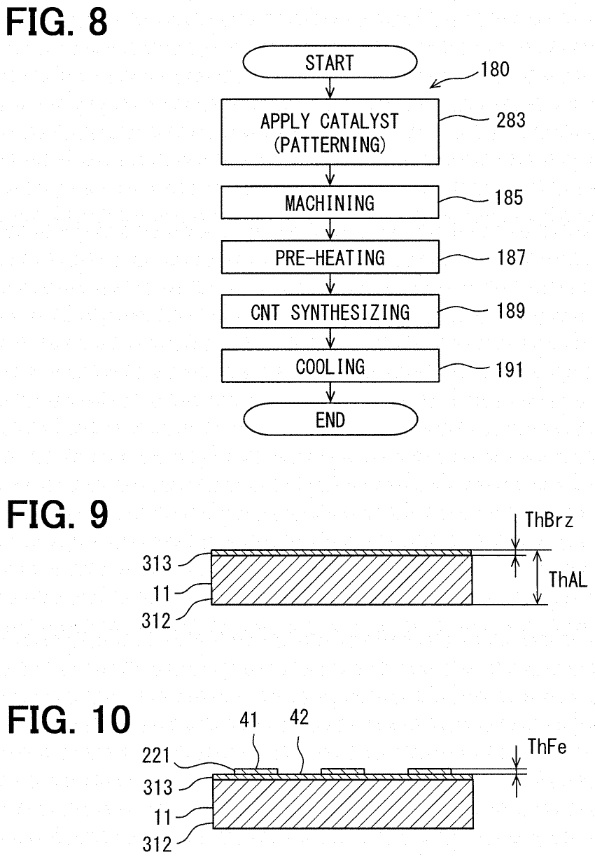

In FIG. 8, in the manufacturing method of this embodiment, a catalyst applying process 283 is adopted. The catalyst applying process 283 is the process of arranging a catalyst. The catalyst applying process 283 forms a partial catalyst layer 221. The catalyst layer 221 can be formed by using a stencil mask or a photolithography. The catalyst applying process 283 is also called a pattern forming process for forming the aligned CNT film 31 into a predetermined pattern shape. The catalyst applying process 283 is a process of disposing the catalyst on the alignment area 41 in which the CNT is formed, without disposing the catalyst on the non-formation area 42 in which the CNT is not formed among the surfaces of the substrate 11. In this embodiment, parameters in a manufacturing process are the same as in the preceding embodiments. The consecutive processes 185-191 are the same as in the preceding embodiments. After the process of applying the catalyst, a shaping process 185 which processes the substrate 11 into a predetermined shape is performed.

In this embodiment, similar to the preceding embodiments, a long aligned CNT film 31 is formed. Further, the aligned CNT film 31 can be partially formed on the substrate 11.

### Third Embodiment

This embodiment is one of modifications based on a basic form provided by the preceding embodiment. In the preceding embodiment, the substrate 11 is made of a single material which is mainly made of aluminum. Alternatively, in this embodiment, the substrate 11 has a main layer 312 and a brazing material layer 313.

In FIG. 9, the substrate 11 has the main layer 312 made of aluminum and the brazing material layer 313. The brazing material layer 313 is an alloy layer which is mainly made of aluminum. The brazing material layer 313 has a fusing point lower than the main layer 312. The brazing material layer 313 has thickness ThBrz. In this embodiment, the aligned CNT film 31 is formed on the brazing material layer 313.

As shown in FIG. 10, the catalyst layer 221 is formed on the brazing material layer 313. The catalyst layer 221 is partially arranged to form the alignment area 41 and non-formation area 42.

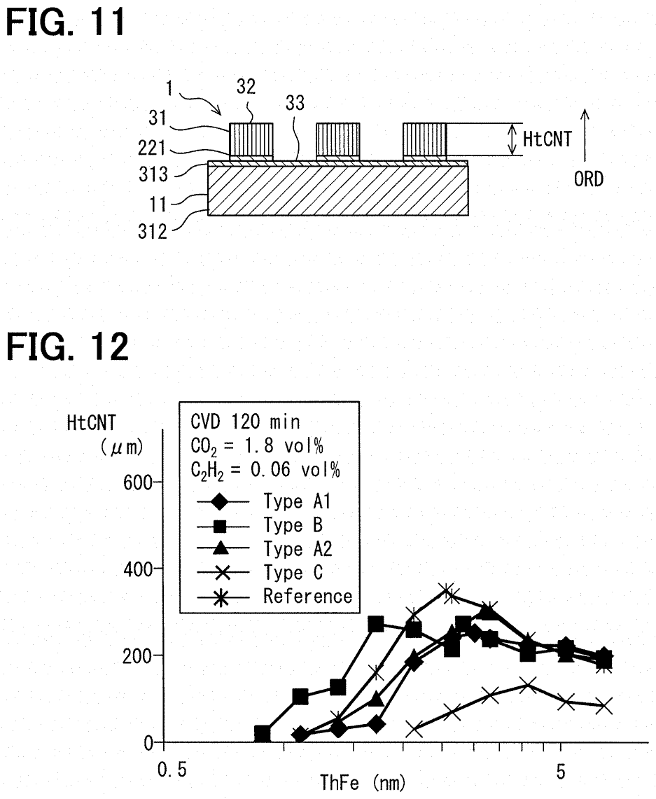

In FIG. 11, the CNT attached member 1 has the aligned CNT film 31 formed on the brazing material layer 313. Also in this embodiment, the aligned CNT film 31 forms the projections 32 and the depressions 33.

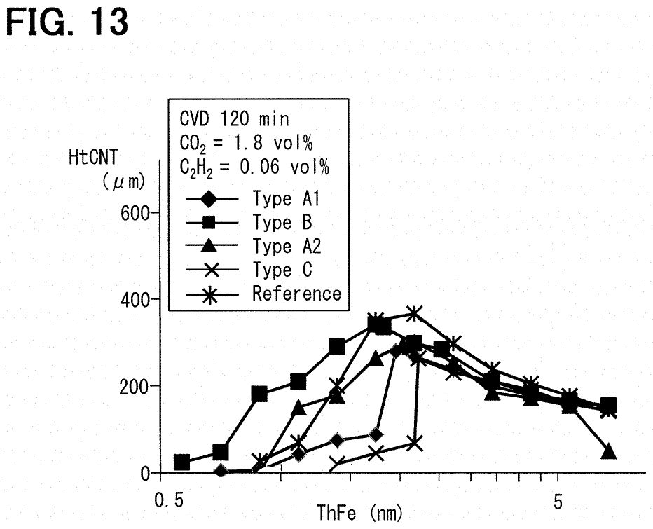

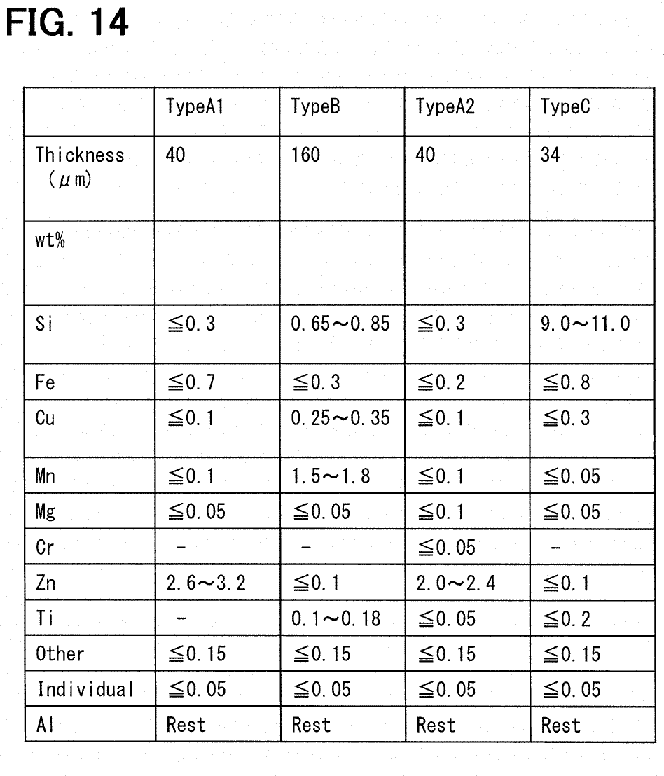

FIG. 12 and FIG. 13 show the diagrammatic charts which show the relationship between the component of the brazing material, and the CNT height HtCNT. FIG. 14 shows the component of the brazing material layer in the sample. A brazing material named Type-A1 is characterized by a main component of aluminum, and containing Zn: 2-3.2%. A brazing material named Type-B is characterized by a main component of aluminum, and containing Si: 0.6-0.9%, Cu: 0.2-0.4%, Mn: 1%-2%, and Ti: 0.1-0.2%. A brazing material named Type-A2 is characterized by less Zn than Type-A1. A brazing material named Type-C is characterized by a main component of aluminum, and containing Si: 9-11%. This diagrammatic chart shows CNT height HtCNT on the following conditions. In the catalyst applying process 183, the catalyst layer 21 is formed by a spattering method on the substrate 11. The catalyst layer 21 is formed by depositing iron in a range of from 0 nm to 7 nm. The substrate 11 is a foil in 0.2 mm-thick. Thickness ThBrz of the brazing material layer 313 is not less than about 10% of thickness ThAL. The preheating process 187 is the same as the preceding embodiments.

In the CNT synthesizing process 189, the source gas of the CNT is supplied on the catalyst layer 21. The source gas is a mixture of acetylene (C₂H₂) and carbon dioxide (CO₂) in volume ratio 1:30. Carbon dioxide occupies 1.8 volume percent (vol %). Acetylene occupies 0.06 volume percent (vol %). A volume CNT synthesizing process is performed for 120 minutes.

In the drawing, a reference article (Reference) without the brazing material layer 313 is illustrated. As shown in the drawing, even if there is the brazing material layer 313, the aligned CNT film 31 with the same height as the reference article is formed. According to this embodiment, the CNT attached member 1 which can be used for brazing is provided. In this case, the CNT attached member 1 is supplied to the brazing process. The CNT attached member 1 is joined to other members so that an article with a predetermined shape is made in the brazing process.

### Fourth Embodiment

This embodiment is one of modifications based on a basic form provided by the preceding embodiment. In the above-mentioned embodiments, a shape of the aligned CNT film 31 can be controlled by the partial catalyst layer 221. Alternatively, an element that positively inhibits synthesis and/or aligned growth of the CNT may be disposed on the surface of the substrate 11. This embodiment uses the rough surface disposed on the surface of the substrate 11 as an inhibitor element.

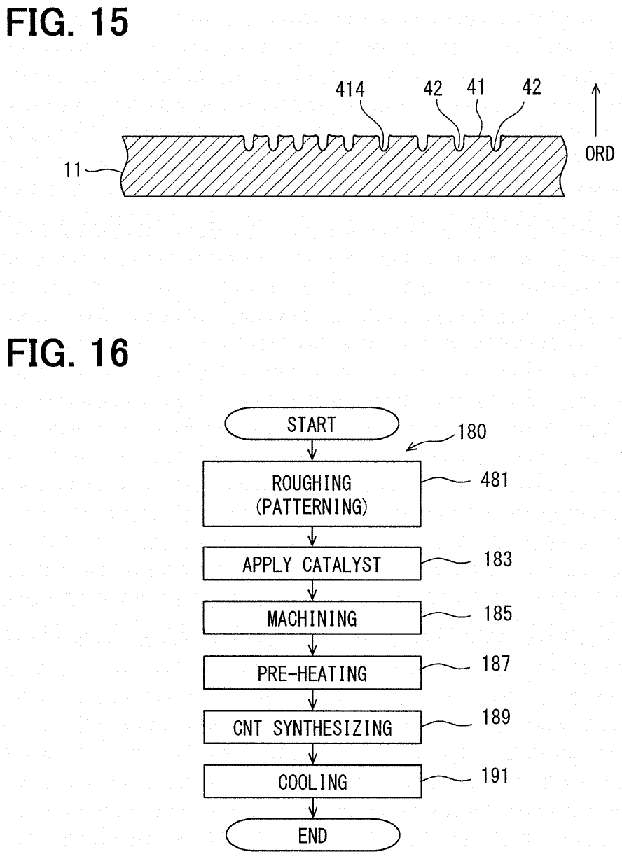

In FIG. 15, the rough surface is formed by a plurality of grooves 414 on the surface of the substrate 11. In this embodiment, the groove 414 is an inhibitor element. In addition, the rough surface is also an inhibitor element. The rough surface corresponds to one groove 414. One groove 414 is defined and formed by a depression in a U shape. The groove 414 is a concaved part from the original surface (flat surface) of the substrate 11. The depression in the U shape provides surfaces which cross to the original surface of the substrate 11. The depression in the U shape is defined and formed by surfaces which orient in different directions from the original surface (flat surface) of the substrate 11. The original surface of the substrate 11 is left behind between two grooves 414. The original surface of the substrate 11 provides the alignment area 41. The groove 414 provides a non-alignment area 43. More specifically, the groove 414 inhibits aligned growth of the CNT. In the non-alignment area 43, the CNT is arranged at random, without being aligned along the alignment direction ORD.

In FIG. 16, in the manufacturing method of this embodiment, a rough surface machining process 481 is adopted. The rough surface machining process 481 forms a partial rough surface on the surface of the substrate 11 by a mechanical or chemical surface treatment to the substrate 11. The rough surface forms a surface rougher than the other parts on the surface of the substrate 11. The rough surface is formed by various surfaces which incline to the flat surface defining the surface of the substrate 11. The rough surface can be formed by scratching the surface of the substrate 11. In addition, the rough surface may be formed by leaving a surface before a polishing work of the substrate 11. The rough surface machining process 481 is also called the pattern forming process for forming the aligned CNT film 31 in a predetermined pattern shape. The rough surface machining process 481 is a process for disposing the inhibitor element. The rough surface machining process 481 is the process of disposing the rough surface with protrusions and depressions on the non-alignment area 43 on which the CNT is not formed. The rough surface has more protrusions and depressions than the surface of the alignment area 41 on which the CNT is formed. In this embodiment, the rough surface is formed by forming the groove 414 on the surface of the substrate 11.

In one example, the substrate 11 is a plate made of aluminum with 99% or more purity. In addition, the substrate 11 may be made of an aluminum alloy. In the rough surface machining process 481, the groove 414 is formed by the scribe device which is used in the semi-conductor manufacturing process. The groove 414 is a groove having a U shape cross section which is 20 micrometers in depth and 10 micrometers in width. The remaining processes 183-191 are the same as in the preceding embodiments. After the process of disposing the inhibitor element provided by the rough surface machining process 481, a shape machining process 185 which processes the substrate 11 into a predetermined shape is performed.

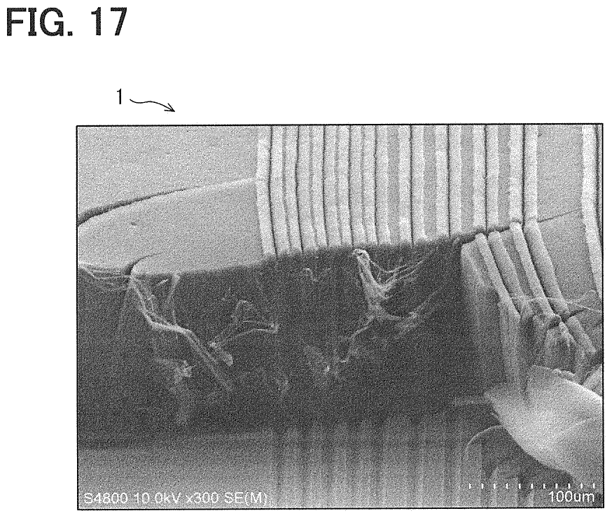

FIG. 17 shows the SEM image of the CNT attached member 1 of an example of this embodiment. FIG. 18 is a diagram for explaining each of parts in the SEM image. FIGS. 17 and 18 corresponds to a perspective view which shows a fracture surface after stripping off a part of the aligned CNT film 31 from the CNT attached member 1 viewed obliquely from above. The upper end surface TP of the aligned CNT film 31 appears in the upper portion of the drawings. The upper end surface TP is formed of the upper end of many CNTs. A crevice CV created when a part of the aligned CNT film 31 is stripped off is viewed at the upper end surface TP. A fracture side SD of the aligned CNT film 31 appears in a middle part of the drawings. The fracture side SD is formed of many CNTs side surfaces. Many lines in vertical direction which show the CNTs are viewed on the fracture side SD. In addition, a wad FZ of random CNTs created when a part of the aligned CNT film 31 is stripped off is viewed at the fracture side SD. The surface of the substrate 11 appears on a lower part of the drawings. The grooves 414 are viewed on the surface of the substrate 11.

As shown in the drawing, a large number of aligned CNTs can be found on the alignment area 41 in a flat surface. Accordingly, the protrusion 32 formed by the aligned CNT film 31 is located on the alignment area 41.

On the other hand, an area in which alignment is randomly broken can be found on the groove 414. Since the CNTs may grow up in a vertical direction to a slant surface caused by the slant surface forming the groove 414, the CNTs growing from opposing slant surfaces inhibit each other, and growth of the CNTs in a perpendicular direction of the substrate is inhibited. Inhibiting of growth appears notably at an upper end surface TP. A thin depression 33 is formed on a position corresponding to the groove 414. This depression 33 is formed by the CNTs with reduced density, in other words, by a cavity. The aligned CNT film 31 is not formed on the groove 414 by the rough surface formed of the groove 414. As a result, the depression 33 is formed on the groove 414. In addition, on a corner as a boundary between a projection 32 and the depression 33, it seems that the upper end portion of CNT inclined a little, and swelled.

In this embodiment, an area of the aligned CNT film 31 in which the CNTs are aligned, and an area on which the CNTs extend with low density or extend randomly are formed on the substrate 11. In other words, the shape of the aligned CNT film 31 is defined by a difference of density or an alignment condition of the CNT, specifically an existence or nonexistence of the alignment. In this embodiment, a plurality of grooves 414 are formed to extend in parallel each other. Alternatively, a plurality of grooves 414 may be formed to extend in a plurality of directions to cross each other. The plurality of grooves 414 may be formed to extend in random directions within the non-alignment area 43.

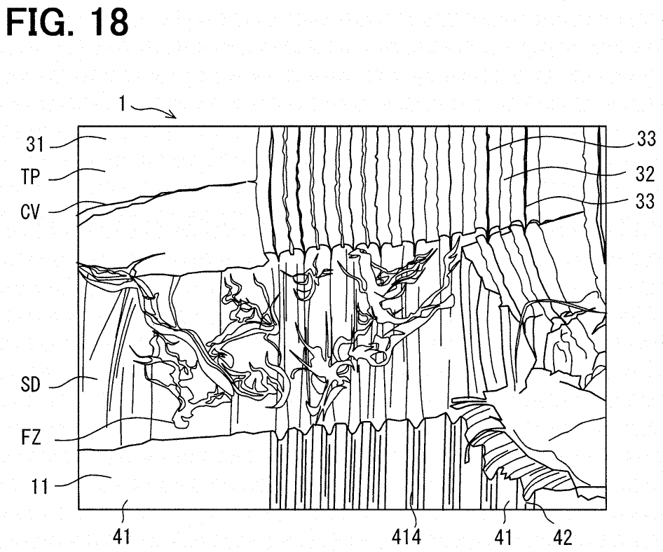

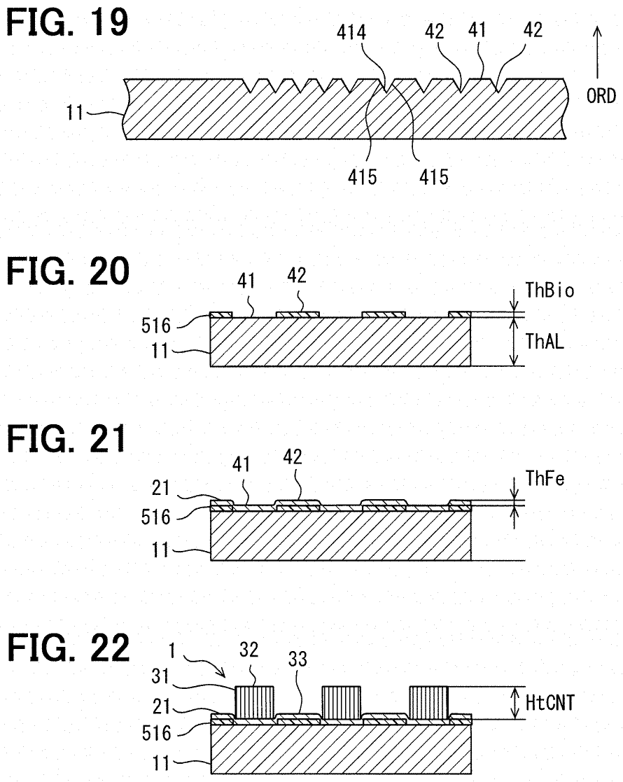

FIG. 19 shows other example of the groove 414. The groove 414 has a cross section in a V shape. One groove 414 is defined and formed by a pair of slant surfaces 415 arranged in a V shape. Since the CNT grows vertically to a surface, the slant face 415 prevents the CNT from growing up to be in the alignment direction ORD within the groove 414. In addition, the shape of the groove 414 is not limited to a U shape and a V shape. The groove 414 may has various shapes, such as a semicircular-shape in cross section or a rectangular-shape in cross section, for example. In this embodiment, similar to the preceding embodiments, the long aligned CNT film 31 is formed. In addition, it is possible to form the aligned CNT film 31 partially on the substrate 11. In addition, the aligned CNT film 31 which occupies a long and narrow area is formed. The aligned CNT films 31 in long and narrow island shapes are formed along the plurality of grooves 414. In another viewpoint, a plurality of linear depressions 33 are formed between the aligned CNT films 31. The plurality of aligned CNT film 31 in island shapes increases an area for heat exchange on a surface of the substrate 11 to a thermal media, such as air. The aligned CNT film 31 in a long and narrow island shape is also a plate shape. The plurality of aligned CNT films 31 in the plate shapes have clearances which can introduce the thermal medium among them. The plurality of aligned CNT films 31 in the plate shapes demonstrate function like fin because the thermal medium flows into the clearances between them.

### Fifth Embodiment

This embodiment is one of modifications based on a basic form provided by the preceding embodiment. In the preceding embodiments, the inhibitor element is provided by the groove 414 and/or the rough surface. Alternatively, a material layer which positively inhibits growth and/or alignment of the CNT may be formed on the surface of the substrate 11. This embodiment uses the organic material layer containing carbon (C) as the inhibitor element.

In FIG. 20, an organic material layer 516 containing carbon is partially formed on the surface of the substrate 11. The organic material layer 516 can be easily formed with a coating, a felt pen, etc. which can be obtained. For example, the organic material layer 516 is formed by painting a part of the surface of the substrate 11 with an oily felt pen. In this embodiment, the organic material layer 516 is an inhibitor element. The organic material layer 516 is arranged on the non-alignment area 43. In other words, the alignment area 41 and the non-alignment area 43 are formed by the organic material layer 516.

As shown in FIG. 21, the catalyst layer 21 is formed also on the organic material layer 516. The organic material layer 516 is arranged to adjoin the catalyst layer 21. The organic material layer 516 reduces the activity of the catalyst which touches the organic material layer 516. The organic material layer 516 may make the catalyst to lose the activity. As a result, the CNT does not grow on the organic material layer 516, or is not aligned. In this embodiment, the catalyst layer 21 is formed on the organic material layer 516. Alternatively, the organic material layer 516 may be disposed on the catalyst layer 21. It is desirable to form the organic material layer 516 be disposed to adjoin the catalyst layer 21. The organic material layer 516 is also called a carbon-containing material layer.

In FIG. 22, the CNT attached member 1 has a projection 32 and a depression 33. A trace of the organic material layer 516 is left behind under the depression 33. This trace is a remaining layer formed by deteriorating the organic material layer 516 by high temperature in the CNT synthesizing process. The organic material layer 516 is mixed with the catalyst layer caused by a high temperature in the CNT synthesizing process, and forms the remaining layer. Therefore, the remaining layer contains carbon and the catalyst layer composing element(s) which constitutes the catalyst layer 21. The remaining layer is also called a carbon-containing material layer and a carbon-containing remaining layer.

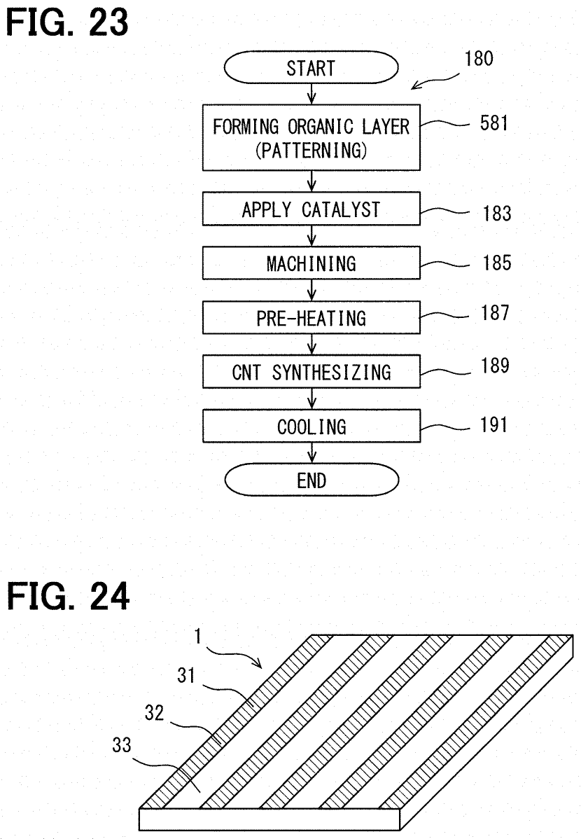

In FIG. 23, in the manufacturing method of this embodiment, the organic layer forming process 581 is adopted. The organic layer forming process 581 is a process of disposing the inhibitor element. In the organic layer forming process 581, the organic material layer 516 containing carbon is disposed on the non-alignment area 43. The organic layer forming process 581 is also called the pattern forming process for forming the aligned CNT film 31 in a predetermined pattern. The remaining processes 183-191 are the same as in the preceding embodiments. After the process of disposing the inhibitor element provided by the organic layer forming process 581, the shape machining process 185 machining the substrate 11 into a predetermined shape is performed. The organic layer forming process 581 may be performed after the catalyst applying process 183. The catalyst applying process 183 may be performed after the shape machining process 185 or after the preheating process 187.

In this embodiment, similar to the preceding embodiments, long aligned CNT film 31 is formed. In addition, it is possible to form the aligned CNT film 31 partially on the substrate 11.

### Sixth Embodiment

This embodiment is one of modifications based on a basic form provided by the preceding embodiment. The aligned CNT film 31 can be formed in a various-shaped substrate. In addition, the aligned CNT film 31 can be formed in various configurations.

The CNT attached member 1 illustrated in FIG. 24 has a configuration which may be called a plate or a foil. The thickness of the CNT attached member 1 is set to be able to maintain its own shape. The CNT attached member 1 provides a surface spreading in two-dimensional manner. The CNT attached member 1 is a configured object which can maintain a shape of surfaces by itself. The CNT attached member 1 may be called an independent two-dimensional structure. The aligned CNT film 31 provides a striped pattern. That is, the aligned CNT film 31 is formed to provide projections 32 and depressions 33 which were arranged in a stripe manner.

### Seventh Embodiment

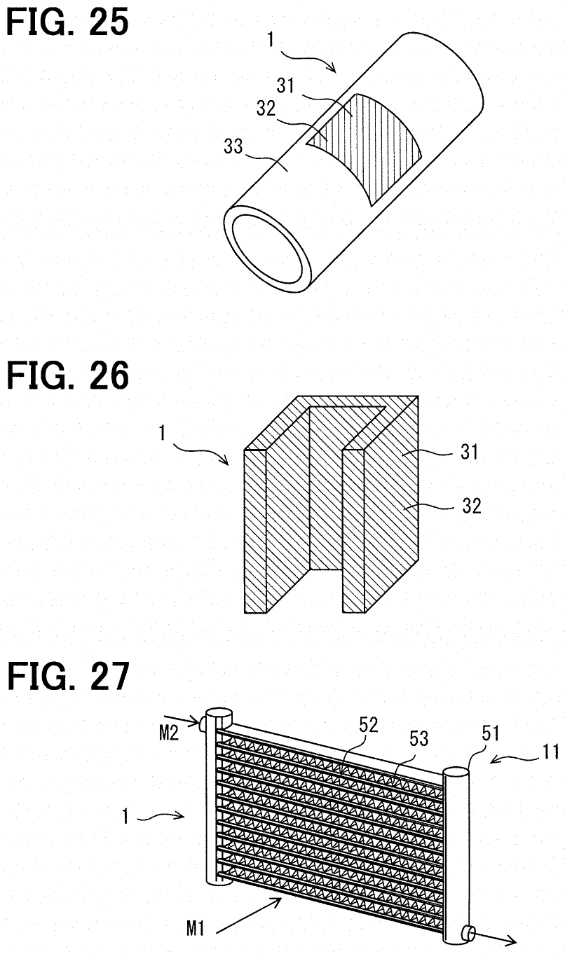

This embodiment is one of modifications based on a basic form provided by the preceding embodiment. The CNT attached member 1 illustrated in FIG. 25 has a configuration which may be called a pipe. The thickness of the CNT attached member 1 is set to be able to maintain its own shape. The CNT attached member 1 provides a curved surface spreading in three-dimensional manner. The CNT attached member 1 is a configured object which can maintain a shape of surfaces by itself. The CNT attached member 1 may be called an independent three-dimensional structure. The aligned CNT film 31 is formed on a surface spreading smoothly and continuously in three dimensions. The aligned CNT film 31 is formed to provide projections 32 which occupy a part of three-dimensional surface, and depressions 33 which adjoin above. The CNT attached member 1 may have various three-dimensional shapes, such as block and a mesh.

### Eighth Embodiment

This embodiment is one of modifications based on a basic form provided by the preceding embodiment. The CNT attached member 1 illustrated in FIG. 26 has a three-dimensional shape. The thickness of the CNT attached member 1 is set to be able to maintain its own shape. The CNT attached member 1 has a plurality of flat surfaces spreading to cross each other. The CNT attached member 1 is formed with a plurality of flat surfaces and small curved surfaces connecting between them. The CNT attached member 1 may be called an independent three-dimensional structure.

In this embodiment, the substrate is formed by bending a plate made of aluminum with 99% of purity into a shape of a bracket. In the manufacturing method of this embodiment, the substrate is installed into an electric furnace and heated up to 600 degrees Celsius (° C.) under an argon flow. Next, the steam from the Ferrocene heated to 80° C. is included in argon. The substrate is exposed to this atmosphere over 3 minutes. Then, the aligned CNT film is synthesized by the same process as in the preceding embodiments.

Further, the inhibitor element may be disposed on the surface of the substrate. In addition, after disposing the inhibitor element on a flat plate, the flat plate may be processed into a three-dimensional shape, and then the aligned CNT film may be synthesized. According to this embodiment, the aligned CNT film is formed on the whole surface of the bracket shaped substrate.

### Ninth Embodiment

This embodiment is one of modifications based on a basic form provided by the preceding embodiment. As shown in FIG. 27, the CNT attached member 1 has a configuration of a heat exchanger which provides heat exchange between two media M1 and M2. The CNT attached member 1 provides complicated various surfaces. Also in this embodiment, the CNT attached member 1 has the substrate 11 and the aligned CNT films 31 and 931 formed on the surface of the substrate 11.

In this embodiment, a plurality of substrates 11, which was machined into shapes for forming the heat exchanger, are combined, and providing a configuration of the heat exchanger. The substrate 11 is aluminum and an aluminum alloy. Brazing material, and aluminum or an aluminum alloy suitable for brazing is exposed to the surface of the substrate 11. The substrate 11 has a pair of headers 51, a plurality of tubes 52 which connect between a pair of headers 51. In addition, the substrate 11 has a plurality of fins 53 for increasing a surface area to a primary medium M1. The primary medium M1 flows on an outside surface of the CNT attached member 1. A secondary medium M2 flows inside of the pair of headers 51 and the plurality of tubes 52.

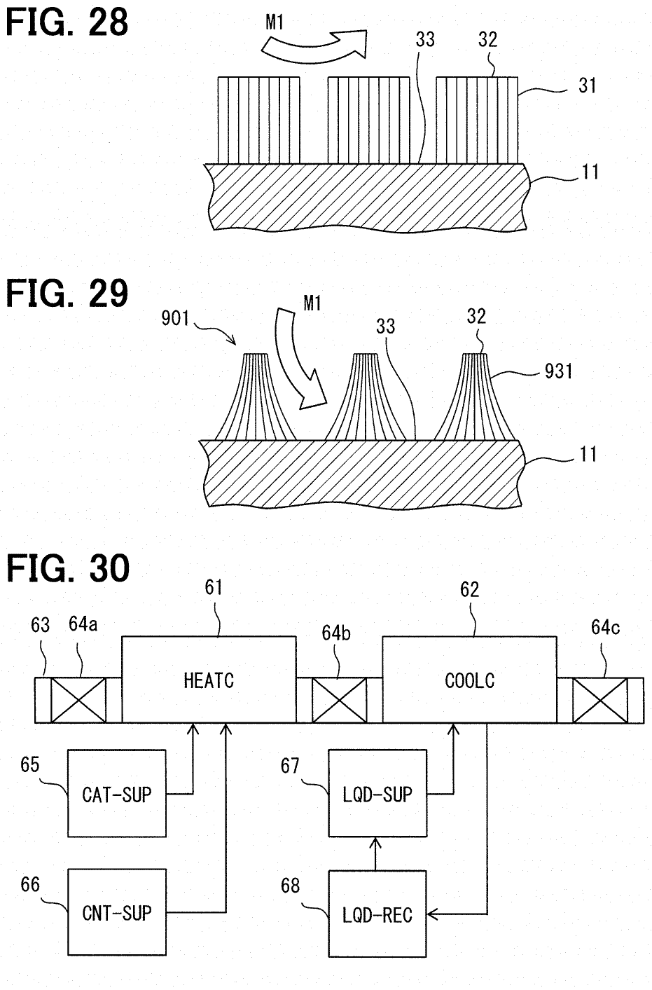

As shown in FIG. 28, the projections 32 and the depressions 33 are formed by the aligned CNT film 31 on the surface of the CNT attached member 1. The primary medium M1 flows in contact with the aligned CNT film 31. However, in the shape illustrated in FIG. 28, the heat exchange of the primary medium M1 and the aligned CNT film 31 may not fully be obtained.

FIG. 29 shows the aligned CNT film 931 which is shaped in this embodiment. The shaped aligned CNT film 931 is in a trapezoid shape. The shaped aligned CNT film 931 has a base portion near the substrate 11, and an end portion distant from the substrate 11. The base portion is thicker than the end portion. The shaped aligned CNT film 931 is shaped to be thick to a side of the substrate 11, and becomes narrow as it is distant from the substrate 11. In the shaped aligned CNT film 931, CNT slightly inclined and extended are included in a bundle of island shaped CNTs. However, many CNTs included in a bundle of island shaped CNTs are still aligned vertically to the surface of the substrate 11. Also in the shaped aligned CNT film 931, it can be said that a plurality of CNTs are aligned vertically to the surface of the substrate 11 in general. The shaped aligned CNT film 931 tends to introduce the primary medium M1 into the depressions 33. As a result, the CNT attached member 1 which can demonstrate heat exchanging performance high as a heat exchanger is manufactured.

The manufacturing device illustrated in FIG. 30 may be assembled by modifying the existing manufacturing device for the heat exchanger. The manufacturing device of the CNT attached member 1 has the heat chamber (HEATC) 61 and the cooling chamber (COOLC) 62 for performing the cooling process.

The heat chamber 61 accommodates a plurality of substrates 11 which is mainly made of aluminum and has brazing material at least on a part. The heat chamber melts the brazing material by heating a plurality of substrates 11, and brazes a plurality of substrates 11. The heat chamber 61 is a brazing furnace for brazing a plurality of members as the heat exchanger. Simultaneously, the heat chamber 61 is also a reactor for synthesizing the CNT. The CNT is synthesized at the same time of the brazing, or at before and after the brazing.

The cooling chamber 62 is a chamber for cooling the CNT attached member 1 which is brazed and formed with the aligned CNT film 31 in the heat chamber 61. The cooling chamber 62 is also a shaping chamber for shaping the aligned CNT film 31 orthopedically. In addition, a preheating chamber for performing a preheating process before the heat chamber 61 may be disposed. The manufacturing device has a gate devices 64a, 64b, and 64c for maintaining atmospheres in the conveying machine 63 and in each chambers 61, 62. The gate devices 64a, 64b, and 64c can be provided by an air curtain or a gate valve.

The manufacturing device has a catalyst supplying machine (CAT-SUP) 65 which supplies the raw material of the catalyst to the heat chamber 61. The catalyst supplying machine 65 supplies the raw material of the catalyst so that the catalyst for synthesizing CNT is disposed on the surface of the substrate 11. Therefore, the heat chamber 61 is a furnace for applying the catalyst on the surface of the substrate 11, in other words, is a reactor for forming the catalyst layer. The catalyst is applied to the substrate 11 at the same time with brazing, at before brazing or at after brazing. The catalyst is applied to the substrate 11 simultaneously with the CNT synthesis or before the CNT synthesis.

The manufacturing device has the CNT material supplying machine (CNT-SUP) 66 which supplies the raw material of the CNT to the heat chamber 61. The raw materials, such as acetylene, are supplied by the CNT material supplying machine 66 into the heat chamber 61, and the CNT is synthesized. The CNT material supplying machine 66 supplies the raw material of the CNT to the heat chamber 61 so that brazing and synthesis of the aligned CNT film 31 is performed in the heat chamber 61. The CNT material supplying machine 66 can contain an apparatus which supplies acetylene, an apparatus which supplies carbon dioxide, and a controller which controls them. When the CNT is synthesized on the surface of the substrate, the controller supplies acetylene with a proper amount for synthesizing the CNT required. Simultaneously, the controller adjusts supplying amounts of acetylene and carbon dioxide so that a volume ratio of acetylene and carbon dioxide is set 1:10 or more and 1:300 or less.

The manufacturing device has the shaping liquid supplying machine (LQD-SUP) 67 which supplies a shaping liquid. The shaping liquid supplying machine 67 is constituted so that the shaping liquid is supplied to the cooling chamber 62. The shaping liquid is ethanol, for example. The shaping liquid is supplied as steam and may be liquefied in the cooling chamber. The manufacturing device has the shaping liquid collecting machine (LQD-REC) 68 for collecting and reusing the shaping liquid. The shaping liquid collecting machine 68 is constituted so that the shaping liquid is collected from the cooling chamber 62.

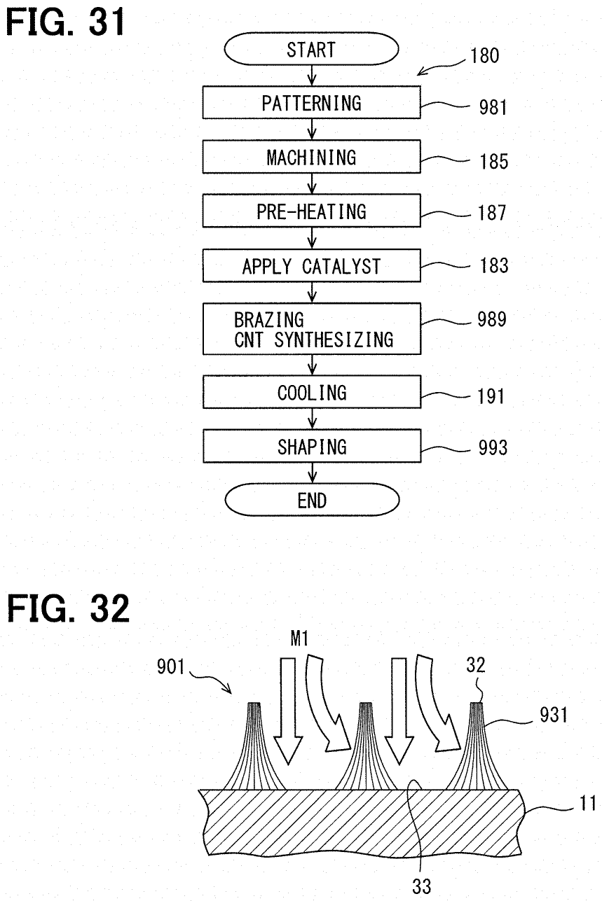

In FIG. 31, in the manufacturing method of this embodiment, a pattern forming process 981 and a shaping process 993 are performed in addition to the above-mentioned process 183-187 and 19. The pattern forming process 981 may be provided by adopting either process disclosed in the preceding embodiments. In this embodiment, the rough surface and/or the organic material layer is adopted as the inhibitor element. These approaches enable to form the aligned CNT film 31 partially, without being dependent on the catalyst. Therefore, it can be performed before the shape machining process 185. In this manufacturing method, the shape machining process 185 is performed before the catalyst applying process 183. The shape machining process 185 is also a process of assembling a plurality of members which form a heat exchanger with the substrates containing the brazing material layer. In this embodiment, the preheating process 187 is performed after the shape machining process 185. Furthermore, the catalyst applying process 183 is performed after the preheating process 187. In the catalyst applying process 183, for example, the catalyst is applied to the preheated substrate 11 by supplying catalyst included gas, such as ferrocene steam, into the preheated heat chamber 61. In this embodiment, the catalyst is applied to the surface of the substrate with the shape of the heat exchanger having a plurality of surfaces.

In this manufacturing method, the process 989 is performed instead of the CNT synthesizing process 189 in the preceding embodiments. The process 989 is performed after the catalyst applying process 183. The process 989 is a process which perform brazing and CNT synthesizing in the common heat chamber 61.

The shaping process 993 shapes the aligned CNT film 31 into a shape suitable for the heat exchanger. The shaping process 993 is also an aggregation process in which a plurality of CNTs are collected or bundled so that an island shape CNTs are thinly shrunk at the distal end portion of the bundle. A liquid can be used to collect a plurality of CNTs and to decrease those spacing. The liquid can also be called a shaping liquid. An example of the shaping liquid is a volatile liquid. By supplying the shaping liquid to the cooling chamber 62, the shaping liquid wets the aligned CNT film 31. In addition, the shaping liquid can be supplied into the cooling chamber 62 as steam, and can turn liquid in the cooling chamber, and wet the aligned CNT film 31. The shaping liquid is evaporated by reducing a shaping liquid steam concentration in atmosphere gas, or by increasing atmosphere temperature, or by elapsing time. In the process of wetting and drying the aligned CNT film 31, a plurality of CNTs are aggregated and bundled. As a result, the aligned CNT film 931 shaped in a trapezoid shape is obtained. A function of the shaping liquid at this time is similar to a function of a hair liquid shaping hair. An organic solvent can be used as the shaping liquid.

According to this embodiment, long CNT can be formed on the surface of the heat exchanger. In addition, the aligned CNT film 31 with a predetermined shape can be formed on the surface of the heat exchanger. Furthermore, a shape of the aligned CNT film 31 can be shaped into a shape suitable for the heat exchanger.

FIG. 32 shows other examples of the shaped aligned CNT film 931. A shape of the aligned CNT film 931 can be adjusted by changing various kinds of conditions in a manufacturing method. For example, it is possible to adjust a shape, i.e., a thinness of the aligned CNT film 931 by a density of the CNTs in the aligned CNT films 931 in a group of island shapes, and a kind of the shaping liquid, an evaporation rate of the shaping liquid, etc. The more the aligned CNT film 931 is thin, the more the thermal medium, such as air is introduced between adjacent two aligned CNT films 931.

The more the aligned CNT film 931 is thin, the more the thermal medium is introduced to near the substrate 11. In addition, a shaped aligned CNT film 931 increases a direct contact surface between the substrate 11 and the thermal medium. In a case of a plurality of aligned CNT films 931 are arranged in a shape of stripes, a shaped aligned CNT film 931 provides a fin-shape which can be called a micro fin. Between those aligned CNT films 931, a passage shape which can be called a micro channel into which the thermal medium can flow is provided. As a result, the carbon nanotube attached member which demonstrates the outstanding heat exchanging performance is provided.

### Other Embodiments

The disclosure in this description is not restricted to the illustrated embodiment. The disclosure includes the illustrated embodiments and modifications by a person skilled in the art based on the illustrated embodiments. For example, disclosure is not limited to the component and/or the combination of the components shown in the embodiments. The disclosure can be carried out with various combinations. The disclosure may use additional parts which can be added to the embodiments. The disclosure may contain modifications in which component and/or element of the embodiments are removed. The disclosure may contain modifications in which component and/or element of the embodiments are exchanged or combined. Technical scope of disclosure is not limited to the embodiments. It should be understood that some disclosed technical scope may be shown by description in the scope of claim, and contain all modifications which are equivalent to and within description of the scope of claim.

In the preceding embodiment, a heat transfer product is illustrated as an application of the CNT attached member. Alternatively, the CNT attached member may be used for various applications. For example, it can be used for a member of electric apparatus, i.e., a battery, a member for building a structure, etc. Partial aligned CNT film 31, i.e., the aligned CNT film 31 formed in a predetermined pattern demonstrates advantages required for each of various applications. In addition, the shaped aligned CNT film also demonstrates an effectiveness required for each of various applications.

In the preceding embodiments, the substrate is made of aluminum or an aluminum alloy. Alternatively, the substrate may be a multilayered material which has an aluminum layer or an aluminum alloy layer on a surface layer.

In the preceding embodiment, the groove 414 is formed on the surface of the substrate 11 by using the scribe device. Alternatively, the rough surface or the groove may be formed by using various metal machining methods, such as a cutting, rolling, polishing, and a chemical attacking.

What is claimed is:

1.-10. (canceled)

11. A carbon nanotube attached member comprising:
a substrate which is mainly made of aluminum; and
a aligned CNT film which is arranged on a surface of the substrate, and includes a plurality of carbon nanotubes having a length of 200 micrometers or longer and being aligned along a predetermined alignment direction, wherein
the aligned CNT film is partially formed on the surface of the substrate, further comprising:
an inhibitor element which inhibits synthesis of and/or aligned growth of the aligned CNT film, and is formed on an area in which the aligned CNT film is not formed, among the surface of the substrate.

12. The carbon nanotube attached member claimed in claim 11, wherein
the inhibitor element has a rough surface having higher or lower parts compared to a surface on which the aligned CNT film is formed.

13. The carbon nanotube attached member claimed in claim 12, wherein
the rough surface is formed of a groove.

14. The carbon nanotube attached member claimed in claim 13, wherein
the groove is defined by slant surfaces arranged in a U shape or a V shape.

15. The carbon nanotube attached member claimed in claim 11, wherein the inhibitor element has a carbon-containing material layer containing carbon.

16. The carbon nanotube attached member claimed in claim 15, further comprising:
a catalyst layer which is disposed on the surface of the substrate and arranged with a catalyst for synthesizing the carbon nanotube, wherein
the carbon-containing material layer contains a catalyst layer composing element and carbon.

17. The carbon nanotube attached member claimed in any claim 11, wherein
the surface of the substrate has
a projection in which the aligned CNT film is formed, and
a depression in which the carbon nanotube is not synthesized, or the carbon nanotube is extended more roughly than the aligned CNT film or is extended with low density.

18. The carbon nanotube attached member claimed in any claim 11, wherein
the substrate has a surface including:
an alignment area in which the aligned CNT film is formed; and
a non-formation area in which the aligned CNT film is not formed.

19. The carbon nanotube attached member claimed in any claim 11, wherein
the substrate has a surface including:
an alignment area in which the aligned CNT film is formed; and
a non-alignment area in which the carbon nanotubes are randomly arranged.

20. The carbon nanotube attached member claimed in any claim 11, wherein
the aligned CNT film has a base portion near the substrate, and an end portion distant from the substrate, and the base portion is thicker than the end portion.

21. A manufacturing method for a carbon nanotube attached member, the method comprising the steps of:
arranging a catalyst for synthesizing a carbon nanotube on a surface of a substrate mainly made of aluminum; and
synthesizing a carbon nanotube on the surface of the substrate in an atmosphere which is supplied with carbon dioxide for maintaining an activity of the catalyst, and volume ratio of carbon dioxide and acetylene being 1:10 or more as a raw material of the carbon nanotube.

22. The manufacturing method for a carbon nanotube attached member claimed in claim 21, wherein
the arranging the catalyst is disposing the catalyst only on an area in which the carbon nanotube is formed, without disposing the catalyst on an area in which the carbon nanotube is not formed among the surface of the substrate, and further comprising:
shaping the substrate into a predetermined shape, before or after disposing the catalyst.

23. The manufacturing method for a carbon nanotube attached member claimed in claim 21, further comprising the steps of:
shaping the substrate mainly made of aluminum into a predetermined shape; and
disposing an inhibitor element which inhibits synthesis of and/or aligned growth of the aligned CNT film, and is formed on an area in which the aligned CNT film is not formed, among the surface of the substrate, wherein
the shaping the substrate into the predetermined shapes after the disposing the inhibitor element.

24. The manufacturing method for a carbon nanotube attached member claimed in claim 23, wherein
the disposing the inhibitor element is disposing a rough surface having higher or lower parts compared to a surface on which the CNT is formed on the area in which the CNT is not formed.

25. The manufacturing method for a carbon nanotube attached member claimed in claim 23, wherein
the disposing the inhibitor element is disposing a carbon-containing material layer containing carbon on the area in which the carbon nanotube is not formed.

26. A device for manufacturing a carbon nanotube attached member, the device comprising:
a heat chamber which accommodates a substrate which is mainly made of aluminum and has a brazing material at least partially, and brazes the substrate by melting a brazing material by heating the substrate; and
a material supplying machine which supplies raw material of the carbon nanotube to the heat chamber so that the brazing and synthesizing an aligned CNT film in which a plurality of carbon nanotubes are aligned along a predetermined alignment direction is performed in the heat chamber.

27. The device for manufacturing a carbon nanotube attached member claimed in claim 26, further comprising:
a catalyst supplying machine which supplies a catalyst to the heat chamber so that the catalyst for synthesizing the carbon nanotube is disposed on a surface of the substrate.

28. The device for manufacturing a carbon nanotube attached member claimed in claim 26, further comprising:
a shaping liquid supplying machine which supplies a shaping liquid for shaping the aligned CNT film.

29. The device for manufacturing a carbon nanotube attached member claimed in claim 28, further comprising:
a shaping liquid collecting machine which collects the shaping liquid.

30. The device for manufacturing a carbon nanotube attached member claimed in claim 29, further comprising:
a cooling chamber which cools the carbon nanotube attached member which is brazed and is formed with the aligned CNT film in the heat chamber, wherein the cooling chamber is configured so that the shaping liquid supplying machine supplies the shaping liquid to the cooling chamber, and the shaping liquid collecting machine collects the shaping liquid from the cooling chamber.
